(19) United States
(12) Patent Application Publication
(10) Pub. No.: US 2009/0063085 A1
(43) Pub. Date: Mar. 5, 2009

(54) PMU TESTING VIA A PE STAGE

(75) Inventors: George W. Conner, Camarillo, CA (US); Allan Joseph Parks, Westlake Village, CA (US)

Correspondence Address: FISH & RICHARDSON P.C., P.O. BOX 1022, MINNEAPOLIS, MN, 55440-1022, US

(73) Assignee: Teradyne,Inc., North Reading, MA (US)

(21) Appl. No.: 11/850,492

(22) Filed: Sep. 5, 2007

(51) Int. Cl. G01R 31/02; G01R 31/28

(52) U.S. Cl. 702/117; 324/555

(57) ABSTRACT

An apparatus for use in testing a device includes a parametric measurement unit to measure a first signal from the device, and pin electronics to provide a second signal to the device. The pin electronics includes circuitry along a path to the device. The parametric measurement unit is electrically connected to the device via the circuitry to receive the first signal via the circuitry.

### TECHNICAL FIELD

This patent application relates generally to testing a device and, more particularly, to providing test signals from the device to a parametric measurement unit (PMU) via a pin electronics (PE) circuit.

### BACKGROUND

Automatic test equipment (ATE) refers to an automated, usually computer-driven, system for testing devices, such as semiconductors, electronic circuits, and printed circuit board assemblies. A parametric measurement unit (PMU) is typically part of ATE. A PMU is used during device testing to provide DC (direct current) test signals to the device to measure parameters, such as voltage and current, at the device. The PMU attempts to ensure that, during testing, proper parameter values are applied to the device under test (DUT). Pin electronics (PE) is also typically part of an ATE. A PE circuit is used during device testing to provide AC (alternating current) test signals to the device and to measure response(s) of the device to those AC test signals.

### SUMMARY

This patent application describes methods and apparatus, including computer program products, for use in providing test signals from a device under test (DUT) to a parametric measurement unit (PMU) via a pin electronics (PE) circuit.

Described herein is an apparatus for use in testing a device. The apparatus comprises a parametric measurement unit to measure a first signal from the device, and pin electronics to provide a second signal to the device. The pin electronics includes circuitry along a path to the device. The parametric measurement unit is electrically connected to the device via the circuitry to receive the first signal via the circuitry. The apparatus may include one or more of the following features, either alone or in combination.

The circuitry along a path to the device may comprise transistors and a impedance circuit. At least one transistor may be on each side of the impedance circuit. Each transistor may comprise a first terminal that is electrically connected to the path to the device, a second terminal that is electrically connected along a path to the parametric measurement unit, and a third terminal that is electrically connected to a controlling device configured to provide a control signal. Each transistor may be configured to receive a control signal and to promote an electrical connection between the first terminal and the second terminal in response to the control signal.

The transistors may comprise field effect transistors (FETs), where the first terminal comprises a source, the second terminal comprises a drain, and the third terminal comprises a gate. The transistors may comprise bipolar junction transistors (BJTs), where the first terminal comprises a collectors, the second terminal comprises an emitter, and the third terminal comprises a base. Combinations of FETs and BJTs may be used.

The controlling device may comprise a processing device configured to generate control signals for the transistor. The impedance circuit may comprise one or more resistors in a configuration that provides a resistance along the path.

The circuitry along a path to the device may comprise a first signal line to the device, a first transistor electrically connected between the first signal line and the parametric measurement unit, a second signal line to the device, and a second transistor electrically connected between the first signal line and the parametric measurement unit. A driver may be electrically connected to the second signal line between the second transistor and the device. The driver may be for pulling-down current from the second signal line.

This patent application also describes a system for testing an electronic device. The system comprises a device interface hoard to hold the electronic device, and a testing device to send test signals to the electronic device and to receive response signals from the electronic device. The response signals result from at least some of the test signals. The system also comprises a processing device to provide control signals to the testing device. The control signals are for affecting operation of the testing device. The testing device, comprises a pin electronics circuit to provide test signals to the device, and a parametric measurement unit to test the device via the pin electronics circuit. The system may include one or more of the following features, either alone or in combination.

The parametric measurement unit may be configured for use in measuring a voltage associated with the device in response to a current forced to the device via the pin electronics circuit. The parametric measurement unit may be configured for use in determining a current associated with the device in response to a voltage forced to the device via the pin electronics circuit.

The pin electronics circuit may comprise differential signal lines to the device. The parametric measurement unit may be configured for use in detecting a resistance between the differential signal lines via the pin electronics circuit. The pin electronics circuit may comprise a signal line to the device, and the parametric measurement unit may be configured to determine a voltage on the signal line in response to a voltage forced onto the signal line by the pin electronics circuit.

The system may further comprise a driver to draw current from a first differential signal line, through the device, to a second differential signal line. The test signals may comprise AC test signals having a frequency of one gigahertz (1 GHz) or more.

This patent application also describes a testing apparatus comprising a first circuit for providing AC test signals to a device, a second circuit for providing DC test signals to the device, and circuitry for electrically connecting the first circuit to the second circuit. The second circuit is configured to measure electrical characteristics of the device via the circuitry and the first circuit. The testing apparatus may include one or more of the following features, either alone or in combination.

The electrical characteristics may include at least one of a voltage at the device and current from the device. The first circuit may comprise one or more signal lines for providing the AC test signals to the device. The circuitry may comprise signal lines to electrically connect, to the second circuit, the one or more signal lines of the first circuit.

The testing apparatus may comprise one or more processing devices for controlling the first circuit to enable measurement of the electrical characteristics by the second circuit. The AC test signals may have a frequency of one gigahertz (1 GHz) or more or of two gigahertz (2 GHz) or more.

The foregoing apparatus, system and/or circuitry may be implemented using a computer program product comprised of instructions that are stored on one or more machine-readable media, and that are executable on one or more processing devices. The foregoing apparatus, system and/or circuitry may be implemented in an apparatus or system that includes one or more processing devices and memory to store executable instructions to implement one of more of the functions described herein.

The details of one or more examples are set forth in the accompanying drawings and the description below. Further features, aspects, and advantages will become apparent from the description, the drawings, and the claims.

### DESCRIPTION OF THE DRAWINGS

FIG. 1 is a block diagram of ATE for testing devices.

FIG. 2 is a block diagram of a tester used in the ATE.

FIG. 3 is a block diagram of circuitry in PMU and PE stages of the ATE for performing voltage testing on the DUT.

FIG. 4 is a block diagram of circuitry in PMU and PE stages of the ATE for performing current testing on the DUT.

FIG. 5 is a block diagram of circuitry in PMU and PE stages of the ATE for determining a resistance value on the DUT.

FIGS. 6 and 7 are block diagrams of circuitry in PMU and PE stages of the ATE for testing diodes on the DUT.

Like reference numerals in different figures indicate like elements.

### DETAILED DESCRIPTION

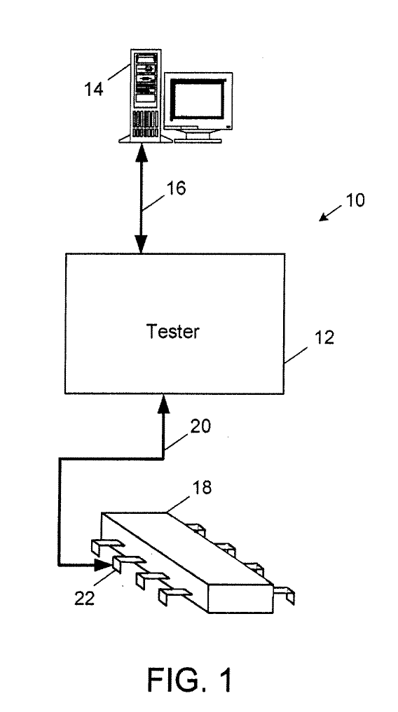

Referring to FIG. 1, an ATE system 10 for testing a device-under-test (DUT) 18, such as a semiconductor device, includes a tester 12. To control tester 12, system 10 includes a computer system 14 that interfaces with tester 12 over a hardwire connection 16. Typically, computer system 14 sends commands to tester 12 to initiate execution of routines and functions for testing DUT 18. Such executing test routines may initiate the generation and transmission of test signals to the DUT 18 and collect responses from the DUT. Various types of DUTs may be tested by system 10. For example, DUTs may be semiconductor devices such as an integrated circuit (IC) chip (e.g., memory chip, microprocessor, analog-to-digital converter, digital-to-analog converter, etc.).

To provide test signals and collect responses from the DUT, tester 12 is connected to one or more connector pins that provide an interface for the internal circuitry of DUT 18. To test some DUTs, e.g., as many as sixty-four or one hundred twenty-eight connector pins (or more) may be interlaced to tester 12. For illustrative purposes, in this example, semiconductor device tester 12 is connected to one connector pin of DUT 18 via a hardwire connection. A conductor 20 (e.g., cable) is connected to pin 22 and is used to deliver test signals (e.g., PMU test signals, PE test signals, etc.) to the internal circuitry of DUT 18. Conductor 20 also senses signals at pin 22 in response to the test signals provided by semiconductor device tester 12. For example, a voltage signal or a current signal may be sensed at pin 22 in response to a test signal and seat over conductor 20 to tester 12 for analysis. Such single port tests may also be performed on other pins included in DUT 18. For example, tester 12 may provide test signals to other pins and collect associated signals reflected back over conductors (that deliver the provided signals). By collecting the reflected signals, the input impedance of the pins may be characterized along with other single port testing quantities. In other test scenarios, a digital signal may be sent over conductor 20 to pin 22 for storing a digital value on DUT 18. Once stored, DUT 18 may be accessed to retrieve and send the stored digital value over conductor 20 to tester 12. The retrieved digital value may then be identified to determine if the proper value was stored on DUT 18.

Along with performing one-port measurements, a two-port test may also be performed by semiconductor device tester 12. For example, a test signal may be injected over conductor 20 into pin 22 and a response signal may be collected from one or more other pins of DUT 18. This response signal is provided to semiconductor device tester 12 to determine quantities, such as gain response, phase response, and other throughput measurement quantities.

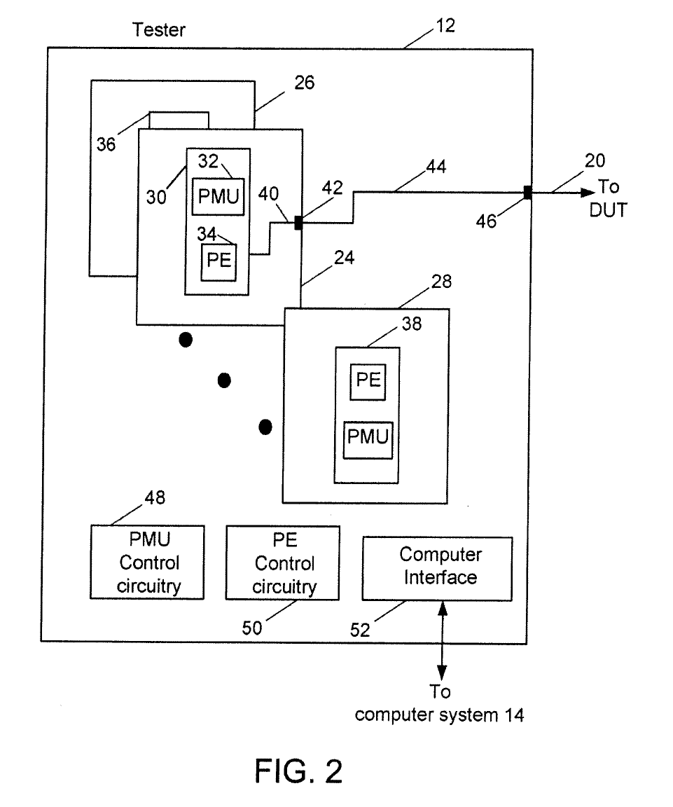

Referring also to FIG. 2, to send and collect test signals from multiple connector pins of a DUT (or multiple DUTs), semiconductor device tester 12 includes an interlace card 24 that can communicate with numerous pins. For example, interface card 24 may transmit test signals to, e.g., 32, 64, or 128 pins and collect corresponding responses. Each communication link to a pin is typically referred to as a channel and, by providing test signals to a large number of channels, testing time is reduced since multiple tests may be performed simultaneously. Along with having many channels on an interlace card, by including multiple interface cards in tester 12, the overall number of channels increases, thereby further reducing testing time. In this example, two additional interface cards 26 and 28 are shown to demonstrate that multiple interface cards may populate tester 12.

Each interface card includes a dedicated integrated circuit (IC) chip (e.g., an application specific integrated circuit (ASIC)) for performing particular test functions. For example, interface card 24 includes IC chip 30 for performing parametric measurement unit (PMU) tests and pin electronics (PE) tests. IC chip 30 has a PMU stage 32 that includes circuitry for performing PMU tests and a PE stage 34 that includes circuitry for performing PE tests. Additionally, interface cards 26 and 28 respectively include IC chips 36 and 38 that include PMU and PE circuitry. Typically PMU testing involves providing a DC voltage or current signal to the DUT to determine such quantities as input and output impedance, current leakage, and other types of DC performance characterizations, PE testing involves sending AC test signals, or waveforms, to a DUT (e.g., DUT 18) and collecting responses to further characterize the performance of the DUT. For example, IC chip 30 may transmit (to the DUT) AC test signals that represent a vector of binary values for storage on the DUT. Once these binary values have been stoned, the DUT may be accessed by tester 12 to determine if the correct binary values have been stored. Since digital signals typically include abrupt voltage transitions, the circuitry in PE stage 34 on IC chip 30 operates at a relatively high speed in comparison to the circuitry in PMU stage 32.

To pass both DC and AC test signals from interface card 24 to DUT 18, a conducting trace 40 connects IC chip 30 to an interface board connector 42 that allows signals to be passed on and off interface board 24. Interface board connector 42 is also connected to a conductor 44 that is connected to an interface connector 46, which allows signals to be passed to and front tester 12. In this example, conductor 20 is connected to interface connector 46 for bi-directional signal passage between tester 12 and pin 22 of DUT 18. In some arrangements, an interface device may be used to connect one or more conductors from tester 12 to the DUT. For example, the DUT (e.g., DUT 18) may be mounted onto a device interface board (DIB) for providing access to each DUT pin. In such an arrangement, conductor 20 may be connected to the DIB for placing test signals on the appropriate pin(s) (e.g., pin 22) of the DUT.

In this example, only conducting trace 40 and conductor 44 respectively connect IC chip 30 and interface board 24 for delivering and collecting signals. However, IC chip 30 (along with IC chips 36 and 38) typically has multiple pins (e.g., eight, sixteen, etc.). that are respectively connected with multiple conducting traces and corresponding conductors for providing and collecting signals from the DUT (via a DIB). Additionally, in some arrangements, tester 12 may connect to two or more DIBs for interfacing the channels provided by interface cards 24, 26, and 28 to one or multiple devices under test.

To initiate and control the testing performed by interface cards 24, 26, and 28, tester 12 includes PMU control circuitry 48 and PE control circuitry 50 that provide test parameters (e.g., test signal voltage level, test signal current level, digital values, etc.) for producing test signals and analyzing DUT responses. The PMU control circuitry and PE control circuitry may be implemented using one or more processing devices. Examples of processing devices include, but are not limited to, a microprocessor, a microcontroller, programmable logic (e.g., a field-programmable gate array), and/or combination(s) thereof. Tester 12 also includes a computer interface 52 that allows computer system 14 to control the operations executed by tester 12 and also allows data (e.g., test parameters, DUT responses, etc.) to pass between tester 12 and computer system 14.

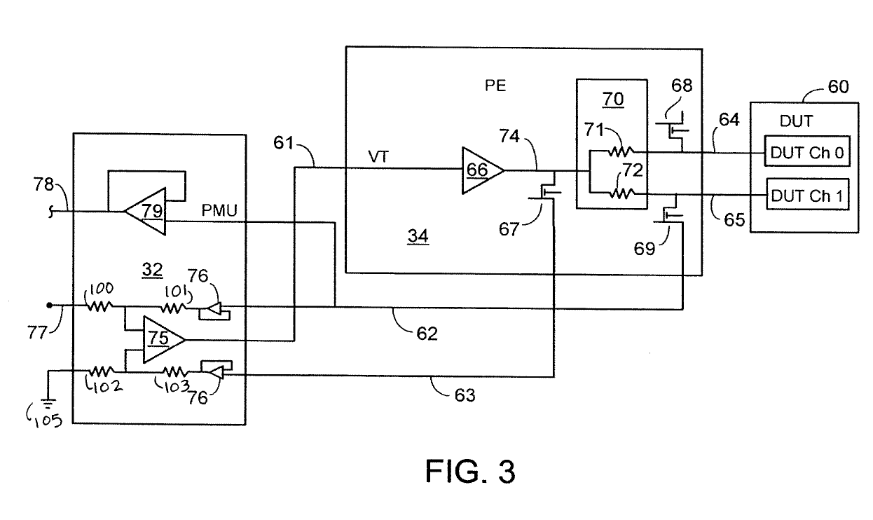

FIG. 3 shows an example of circuitry included in the PMU stage and the PE stage described above. In this implementation, PMU stage 32 is electrically connected to PE stage 34 in order to receive test signals from a DUT 60 via PE stage 34. In FIG. 3, the electrical connection is implemented via signal lines 61 to 63. However, electrical connection does not require a direct physical connection, as shown in FIG. 3. Rather, an electrical connection may include intervening passive or active electronic components between the PE stage and the PMU stage. Likewise, any electrical connection may include non-wired electrical connections, such as those produced by a transformer or wireless transmission medium.

In FIG. 3, there are two signal lines 64, 65 per PE stage. However, in other implementations, there may be only one signal line per PE stage. Signal lines 64 and 65 may be differential signal lines to provide differential AC signals to DUT 60. Each signal line may correspond to a channel on the DUT (e.g., CH0 and CH1 of DUT 60).

PE stage 34 includes an amplifier 66, transistors 67, 68, 69 and a resistive (or impedance) circuit 70. Other components (not shown) may also be included in PE stage 34. Amplifier 66 may receive a voltage signal, VT, and output voltage and current to DUT 60 via resistive circuit 70. In this example, resistive circuit 70 includes one resistor 71, 72 per signal line 64, 65. However, more than one resistor may be included per signal line, and such resistor(s) may be in any series/parallel combination. Likewise, resistive circuit 70 may include additional components, such as capacitors, inductors, transistors, transformers, etc. in place of, or in addition to, resistors.

Transistors 67, 68, and 69 are field effect transistors (FETs) in this example, however, any other type of transistor may be used, such as bipolar junction transistors (BJTs). More than one transistor (not shown) may be used in place of the individual transistors 67, 68, and 69. Transistor 67 is electrically connected source-to-drain between the output 74 of amplifier 66 and PMU stage 32; transistor 68 maybe electrically connected (not shown) source-to-drain between first signal line 64 and PMU stage 32; and transistor 69 is electrically connected source-to-drain between second signal line 65 and PMU stage 32. Each transistor 67, 68, and 69 is controlled by a processing device, such as computer 14 or a controller within tester 12. That is, the processing device provide signals to the gates of the transistors to turn them on and off, i.e., to drive the transistors to conduction or to prevent them from conducting. In a BJT configuration, base, emitter, and collector terminals substitute for the gate, drain and source terminals.

During AC testing, AC signals may be generated in PE stage 34 by gating transistors 68 and 69. That is, AC signals may be generated in PE stage 34 by turning transistors 68, 69 on and off (i.e., making them conductive and non-conductive, respectively) at a desired frequency. Alternatively, a single-ended driver, a differential driver, or any type of signal source connected to lines 64 and 65 may be used to provide the AC signals. The resulting AC signals are output to DUT 60, and reactions thereto measured by the ATE. The AC signals may have a frequency up to one gigahertz (1 GHz), 2 GHz, 10 GHz, or more.

PMU stage 32 may measure PMU (e.g., DC) test signals via PE stage 34. More specifically, as shown in FIG. 3, PMU stage 32 is electrically connected to PE stage 34 via transistors 67, 69 and, in some cases, via transistor 68 (connection not shown in FIG. 3). Alternatively, a different PMU stage (not shown) may be electrically connected to PE stage 34 via transistor 68. The PMU stage include various circuit elements, as described below.

The ATE is capable of operation in a force current, measure voltage mode. In this mode, current is forced to the DUT over signal line 65, and a voltage output of the DUT is measured by the ATE in response to that current. Referring to FIG. 3, an input (not shown) to control signal terminal 77 causes an amplifier 75 in PMU stage 32 to provide a voltage signal, VT, along line 61 to amplifier 66 in PE stage 34. The resulting output current of amplifier 66 (or a portion thereof) is provided, via resistive circuit 70, to the DUT over signal line 65. The gate of transistor 69 receives a control signal, which drives transistor 69 to conduction. Accordingly, the voltage that appears on signal line 65 as a result of the current provided to DUT 60 passes through transistor 69 to PMU stage 32 over signal line 62. The voltage is also applied to amplifier 79, from which it may be passed to a processing device (not shown) or the like for analysis via terminal 78. The voltage may also act as feedback to amplifier 75 to regulate the voltage signal, VT on line 61. The same type of force current, measure voltage process may be used for signal line 64.

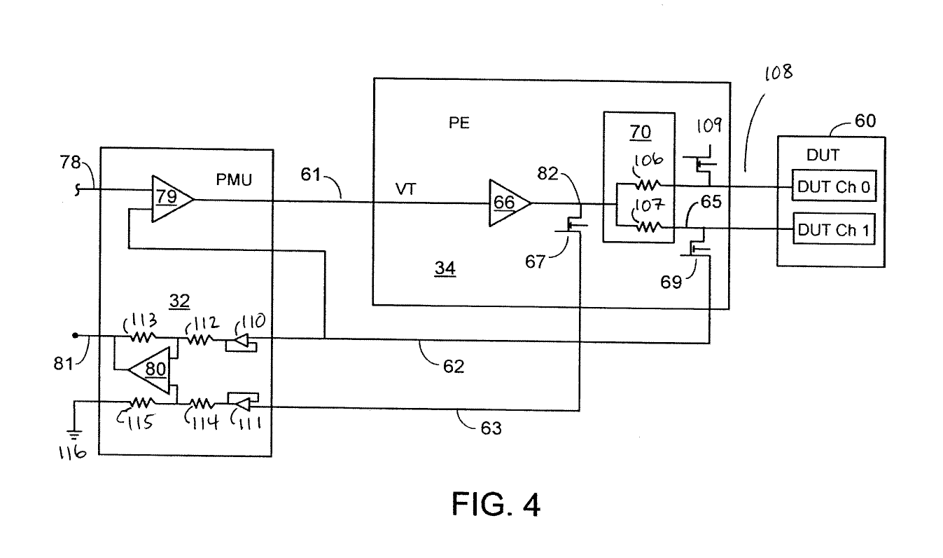

The ATE is also capable of operation in a force voltage, measure current mode. In this mode, voltage is forced to the DUT over a signal line, and a current output of the DUT is measured by the ATE in response to that voltage. Referring to FIG. 4, an input (not shown) to input terminal 78 amplifier 79 in PMU stage 32 provides a voltage signal, VT, along line 61 to amplifier 66 in PE stage 34. The resulting output voltage of amplifier 66 (or a portion thereof) is provided, via resistive circuit 70, to the DUT over signal line 65. The gates of transistors 67 and 69 receive control signal(s), which drive transistor 67 and 69 to conduction. The current (e.g., leakage current) that appears on signal line 65 as a result of the voltage provided to DUT 60 passes through resistive circuit 70. Signal lines 62 and 63 may be high impedance lines to reduce or prevent current flow through those signal lines. The voltages before and after resistive circuit 70 pass, via signal lines 62 and 63 respectively to PMU stage 32. There, they are applied to an amplifier 80, such as a differential amplifier, which obtains the difference in those voltages, and which outputs the difference via terminal 81 to a processing device, such as that described above. This difference constitutes the voltage drop across resistive circuit 70. Knowing this voltage drop, and the resistance of resistive circuit 70, the processing device is able to determine, using Ohm's law, the current through resistive device 70. This current corresponds to the current output of a DUT channel. The voltage at node 65 is also fed back to an amplifier 79 in PMU stage 32, and may be used to regulate the voltage signal, VT, on line 61.

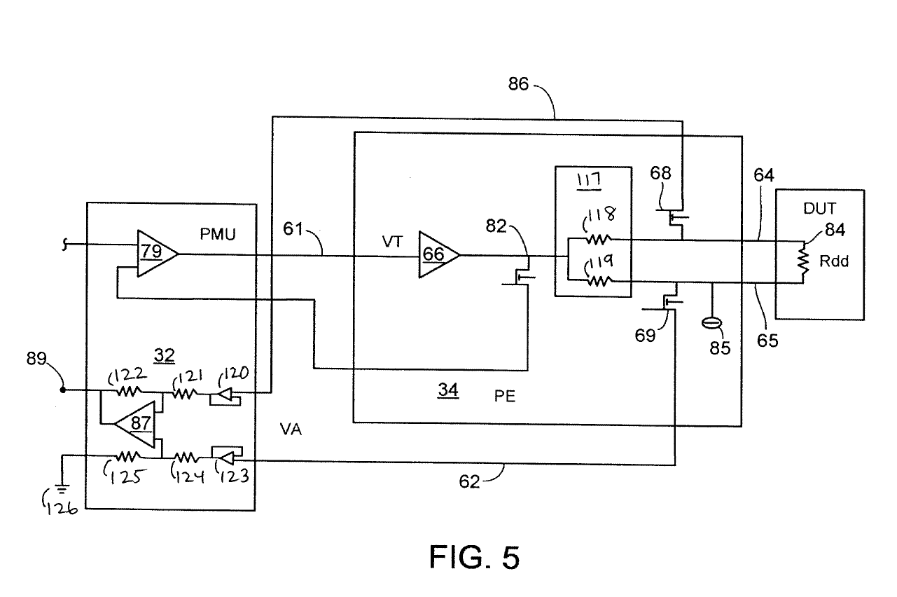

The ATE is also capable of detecting a resistance between two differential signal lines. Referring to FIG. 5, in this configuration, signal lines 64 and 65 are differential signal lines, which are electrically connected via a resistive circuit 84 (Rdd). As above, resistive circuit 84 may be any type of circuit that has impedance, and may include any number of resistors, capacitors, inductors and/or other circuit elements.

In the configuration of FIG. 5, device 85 is configured to drive current from first signal line 65, through resistive circuit 84, to second signal line 64. Device 85 may include a single-ended driver, a differential driven or any other type of current source. A corresponding current source may also be connected to line 64. The resulting current through resistive circuit 84 creates a voltage difference between signal lines 64 and 65, which were previously at about the same voltage. Transistors 68 and 69 are driven to conduction by control signals from the processing device. The signal lines 62 and 86 of transistor 68 and 69, respectively feed back to PMU stage 32, thereby providing the voltages at signal lines 65 and 64 to PMU stage 32. At PMU stage 32, these voltages are provided to an amplifier 87, such as a differential amplifier, which generates a signal at terminal 89 that corresponds to the difference between the voltages (i.e., the voltages of signal lines 64 and 65). Knowing this voltage difference, and the current through differential signal lines 64 and 65, the processing device is able to determine, using Ohm's law, the resistance of resistive circuit 84. The voltage at node 82 is also fed hack to amplifier 79 in PMU stage 32 to regulate the voltage signal, VT, on line 61.

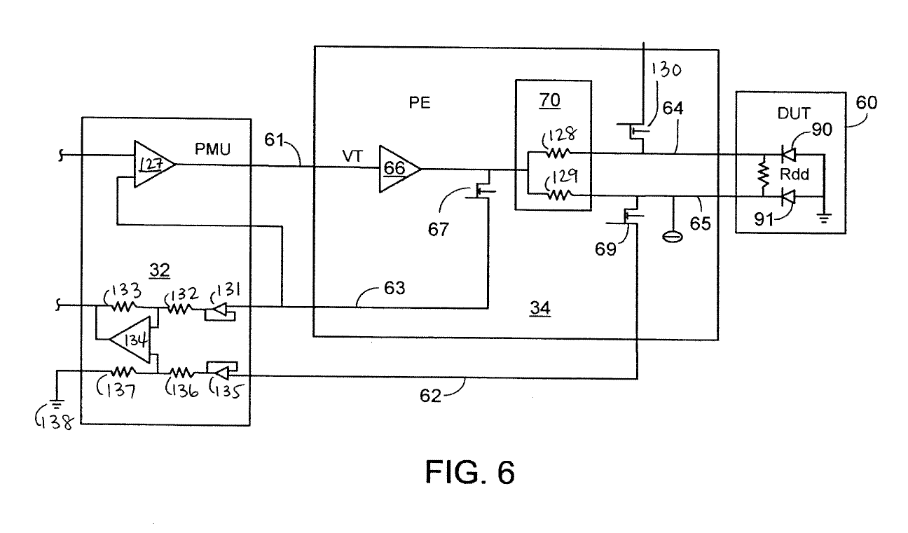

The ATE is also, capable of detecting defects in clamping diodes on DUT communication channels. Referring to FIG. 6, in this configuration, signal lines 64 and 65 are terminated with diodes 90, 91 at DUT 60. A voltage signal is applied from amplifier 66, through resistive circuit 70, to signal line 65. Another voltage signal may be applied to signal line 65. If a diode is operating properly the voltage on the corresponding signal line should clamp to a predefined value. For example, in the configuration shown in FIG. 6, a negative voltage (e.g., −1V) is applied to signal line 65. Diode 91 should clamp that voltage to a predefined voltage (e.g., −7/10V) on signal line 65. Signal line 62 feeds-back to PMU stage 32 the voltage at signal line 65 when transistor 69 is driven to conduction. This voltage may be compared to a predefined voltage (e.g., VT), and the result output to the processing device. If the result is outside the expected operational range of diode 91, the processing device will determine that there is a problem with diode 91, e.g., that it is shorted or open. The same process may be performed for signal line 64.

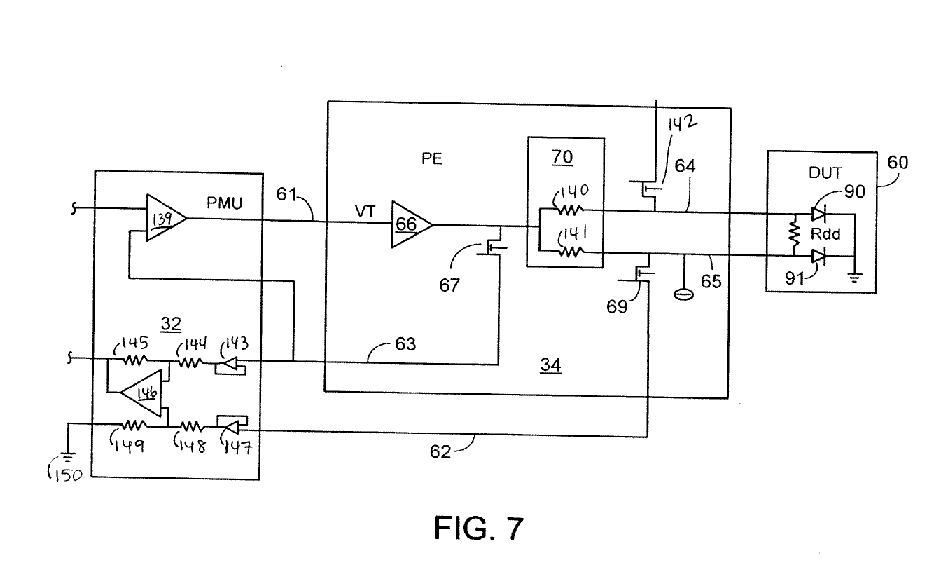

Likewise, if the diodes are configured as shown in FIG. 7, the same process as described above may be performed, except with positive voltages. That is, a positive voltage (e.g., 1V) is applied to signal line 65. Diode 91 should clamp that voltage to a predefined voltage (e.g., 7/10V) on signal line 65. If it does not, the processing device will determine that there is a problem with the diode. As shown in FIGS. 6 and 7, feedback line 63 may be used to regulate the voltage signal, VT, based on the output of amplifier 66.

in other implementations, current signals, instead of voltage signals, may be used to test the diodes of FIGS. 6 and 7. In the case of a current signal, the processing device detects, or does not detect, current flow to the DUT, and judges diode operation accordingly.

In one implementation, PMU stage 32 maybe implemented via an Analog Devices® AD5522 PMU chip; however, other PMUs may be used.

The ATE described herein is not limited to use with the hardware and software described above. The ATE can be implemented in digital electronic circuitry, or in computer hardware, firmware, software, or in combinations thereof.

The ATE can be implemented, at least in part, via a computer program product, i.e., a computer program tangibly embodied in an information carrier, e.g., in a machine-readable storage device or in a propagated signal, for execution by, or to control the operation of, data processing apparatus, e.g., a programmable processor, a computer, or multiple computers. A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a communication network.

Method steps associated with implementing the ATE can be performed by one or more programmable processors executing one or more computer programs to perform the functions of the ATE. All or part of the ATE can be implemented as, special purpose logic circuitry, e.g., an FPGA (field programmable gate array) and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. Elements of a computer include a processor for executing instructions and one or more memory devices for storing instructions and data.

Elements of different embodiments described herein may be combined to form other embodiments not specifically set forth above. For example, combinations of the circuitry described herein may be used to measure the resistance of a resistive circuit and to test the operation of diodes at the same time. These tests may be performed on individual signal lines or on multiple (e.g., two or more) signal lines in parallel.

Other embodiments not specifically described herein are also within the scope of the following claims.

What is claimed is:

1. An apparatus for use in testing a device, comprising:
a parametric measurement unit to measure a first signal from the device; and
pin electronics to provide a second signal to the device, the pin electronics comprising circuitry along a path to the device;
wherein the parametric measurement unit is configured to send a third signal to the pin electronics, the third signal being used to generate the second signal;
wherein the parametric measurement unit is electrically connected to the device via the circuitry to receive the first signal via the circuitry.

2. The apparatus of claim 1, wherein the circuitry further comprises an impedance circuit at least one transistor on each side of the impedance circuit.

3. The apparatus of claim 2, wherein each transistor comprises a first terminal that is electrically connected to the path to the device, a second terminal that is electrically connected along a path to the parametric measurement unit, and a third terminal that is electrically connected to a controlling device configured to provide a control signal; and
wherein each transistor is configured to receive a control signal and to promote an electrical connection between the first terminal and the second terminal in response to the control signal.

4. The apparatus of claim 3, wherein the transistors comprise field effect transistors, the first terminal comprises a source, the second terminal comprises a drain, and the third terminal comprises a gate.

5. The apparatus of claim 3, wherein the transistors comprise bipolar junction transistors, the first terminal comprises a collector, the second terminal comprises an emitter, and the third terminal comprises a base.

6. The apparatus of claim 3, wherein the controlling device comprises a processing device configured to generate control signals for the transistor.

7. The apparatus of claim 2, wherein the impedance circuit comprises one or more resistors in a configuration that provides a resistance along the path.

8. The apparatus of claim 1, wherein the circuitry comprises:
a first signal line to the device;
a first transistor electrically connected between the first signal line and the parametric measurement unit;
a second signal line to the device; and
a second transistor electrically connected between the second signal line and the parametric measurement unit.

9. The apparatus of claim 8, further comprising:
a driver electrically connected to the second signal line between the second transistor and the device, the driver for pulling-down current from the second signal line.

10. A system for testing an electronic device, comprising:
a device interface board to hold the electronic device;
a testing device to send test signals to the electronic device and to receive response signals from the electronic device, the response signals resulting from at least some of the test signals; and
a processing device to provide control signals to the testing device, the control signals to affect operation of the testing device;
wherein the testing device comprises:
a pin electronics circuit to provide test signals to the device, the pin electronics circuit comprising at least two transistors; and
a parametric measurement unit to test the electronic device via the pin electronics circuit and to send a DC signal to the pin electronics circuit;
wherein the at least two transistors are configured to generate an AC signal from the DC signal.

11. The system of claim 10, wherein the parametric measurement unit is configured for use in measuring a voltage associated with the device in response to a current forced to the device via the pin electronics circuit.

12. The system of claim 10, wherein the parametric measurement unit is configured for use in determining a current associated with the device in response to a voltage forced to the device via the pin electronics circuit.

13. The system of claim 10, wherein the pin electronics circuit comprises differential signal lines to the device; and
wherein the parametric measurement unit is configured for use in detecting a resistance between the differential signal lines via the pin electronics circuit.

14. The system of claim 13, further comprising:
a driver to draw current from a first differential signal line, through the device, to a second differential signal line.

15. The system of claim 14, wherein the pin electronics circuit comprises a signal line to the device; and
wherein the parametric measurement unit is configured to determine a voltage on the signal line in response to a voltage forced onto the signal line by the pin electronics circuit.

16. The system of claim 10, wherein the test signals comprise AC test signals having a frequency of one gigahertz (1 GHz) or more.

17. A testing apparatus comprising:
a first circuit for providing AC test signals to a device, the first circuit comprising at least two transistors;
a second circuit for providing DC test signals to the device and for providing a voltage signal to the first circuit; and
circuitry for electrically connecting the first circuit to the second circuit;
wherein the second circuit is configured to measure electrical characteristics of the device via the circuitry and the first circuit; and
wherein the at least two transistors are configured to generate the AC test signal from the voltage signal.

18. The testing apparatus of claim 17, wherein the electrical characteristics comprise at least one of a voltage at the device and current from the device.

19. The testing apparatus of claim 17, wherein the first circuit comprises one or more signal lines for providing the AC test signals to the device; and
wherein the circuitry comprises signal lines to electrically connect, to the second circuit, the one or more signal lines of the first circuit.

20. The testing apparatus of claim 17, further comprising one or more processing devices for controlling the first circuit to enable measurement of the electrical characteristics by the second circuit.

21. The testing apparatus of claim 17, wherein the AC test signals have a frequency of one gigahertz (1 GHz) or more.

22. The testing apparatus of claim 17, wherein the AC test signals have a frequency of two gigahertz (2 GHz) or more.
